(19) United States
(12) Patent Application Publication
(10) Pub. No.: US 2010/0209614 A1
(43) Pub. Date: Aug. 19, 2010

(54) COATING METHOD, AND COATING APPARATUS

(76) Inventors: Kazuhiko Sakata, Tokyo (JP); Kiyoshi Endo, Kanagawa (JP)

Correspondence Address: FRISHAUF, HOLTZ, GOODMAN & CHICK, PC, 220 Fifth Avenue, 16TH Floor, NEW YORK, NY, 10001-7708, US

(21) Appl. No.: 12/733,818

(22) PCT Filed: Oct. 17, 2008
(86) PCT No.: PCT/JP2008/068857

§ 371 Date: Mar. 22, 2010

(30) Foreign Application Priority Data
Nov. 1, 2007 (JP) 2007-284895

(51) Int. Cl. B05D 1/36; B05C 5/00

(52) U.S. Cl. 427/402; 427/74; 427/64; 118/313

(57) ABSTRACT

The invention provides a coating method by which plural coating solutions of a coating solution formed from organic EL material for formation of an organic EL layer in an organic EL element and another coating solution formed from organic photoelectric conversion element material for formation of an organic photoelectric conversion element layer can be coated to prepare a multilayer film with no damage of the organic EL layer and organic photoelectric conversion element layer, and also provides a coating apparatus with the coating method. It is a feature in the coating method that plural coating units each facing a backup roll and sandwiching a long length support with the backup roll are provided, and plural coating solutions are coated onto the support by the plural coating units to form a multilayer coating film, wherein the moving support is wound up by the continuously moving backup roll supporting the support.

### TECHNICAL FIELD

The present invention relates to a coating method to form a multilayer coating film layered on a support by coating plural coating solutions, and a coating apparatus thereof.

### BACKGROUND

A coating film obtained by coating a functional coating solution (hereinafter, referred to also as a coating solution) is utilized for electrode material for display devices of a liquid crystal display, a plasma display, inorganic electroluminescence and organic electroluminescence (hereinafter, referred to as organic EL), elect ode material for optical elements of light emitting apparatuses fitted with inorganic and organic elements, a touch panel material, and materials for an organic photoelectric conversion element and a solar battery. In the case of the foregoing display devices and optical elements, a glass substrate is mainly employed as a support, but in recent years, the glass substrate has been considered to be replaced by a film substrate because of a trend of use of flexible and thin films. The foregoing coating film applied in the organic EL element and the organic photoelectric conversion element is formed as a multilayer coating film layered by coating plural coating solutions

As a method of forming (film-forming) the foregoing coating film on a support, the method is mainly a vacuum depositing film formation method such as a vacuum evaporation method, a sputtering method, an ion plating method, a plasma CVD method, a thermal CVD method or the like, which is commonly known. However, in the case of the foregoing methods, there appeared problems such as low efficiency in the use of coating material, and productivity exhibiting low production speed. In contrast, since coating by a coating system employing a coating apparatus improves not only the efficiency in the use of a coating solution (coating material) but also the production speed, formation of the coating film by the coating system has been studied.

With regard to formation of the foregoing coating film, it is disclosed that at least any of layers constituting an organic EL element is coated employing a slot type coater (refer to Patent Document 1, for example).

With respect to production of an electrooptic panel, it is disclosed that coating is conducted by an inkjet coating system to form the foregoing coating film (refer to Patent Document 2, for example).

Patent Document 1: Japanese Patent O.P.I. (Open to Public Inspection) Publication No. 2001-6875

Patent Document 2: Japanese Patent O.P.I. Publication No. 2004-295093

### DISCLOSURE OF THE INVENTION

### Problems to be Solved by the Invention

It is disclosed in Patent Document 1 that a single layer is coated with a slot type coater. It is disclosed in Patent Document 2 that a single layer is coated by inkjet. Accordingly, in order to prepare a multilayer coating film, the same repetitive processes corresponding to the number of the multilayer had to be repeatedly conducted in such a way that the first layer is coated, followed by drying and winding up; the second layer is subsequently coated, followed by drying and winding up; and so on. That is, every time a process of coating each layer was passed, in other words, with respect to each pass, a support on which a coating film was formed had to be wound up.

The weak coating film surface of each of an organic EL layer in an organic EL element and an organic photoelectric conversion element layer in an organic photoelectric conversion element is easy to be damaged during the winding up by contact between the surface of a coating film and the base surface of a support on the opposite side of the coating film. Accordingly, when the number of repetitive wind-up is large, a chance to damage tends to become large, resulting in quality degradation of the coating film surface and yield drop of products.

Further, in order to form a multilayer coating film, a multilayer coater to simultaneously coat plural layers in which plural slits to eject a coating solution to one slot type coater are provided has been known so far. However, since a coating solution composed of an organic EL material used for an organic EL layer and another coating solution composed of an organic photoelectric conversion element material used for an organic photoelectric conversion element layer as the organic electronics material were easy to be mutually mixed, it was difficult to simultaneously coat plural layers employing a multilayer coater.

The present invention was made on the basis of the above-described situation, and it is an object of the present invention to provide a coating method by which plural coating solutions such as a coating solution formed from an organic EL material used for formation of an organic EL layer in an organic EL element, and another coating solution formed from an organic photoelectric conversion element material used for formation of an organic photoelectric conversion element layer can be coated to prepare a multilayer film with no damage of the organic EL layer and the organic photoelectric conversion element layer, and also to provide a coating apparatus with the coating method.

### Means to Solve the Problems

The above-described object is accomplished by the following methods and structures.

(Structure 1) A coating method to form a multilayer coating film layered by coating plural coating solutions onto a long length support, comprising the steps of providing plural coating units each facing a backup roll and sandwiching the support with the backup roll, and coating the plural coating solutions onto the support by the plural coating units to form the multilayer coating film.

(Structure 2) The coating method of Structure 1, wherein at least one solvent in the foregoing plural coating solutions has a boiling point of 120° C. or less.

(Structure 3) The coating method of Structure 1 or 2, wherein each single layer of the multilayer coating film has a wet coating layer thickness of 0.5-10 μm.

(Structure 4) The coating method of any one of Structures 1-3, wherein each of the plural coating units coats a single coating solution.

(Structure 5) The coating method of any one of structures 1-4, wherein the plural coating units comprise at least one of an inkjet coating system and a slot type coater coating system having a slit to eject the coating solution in a width direction of the support.

(Structure 6) The coating method of any one of Structures 1-5, wherein the coating solution comprises an organic electronics material.

(Structure 7) The coating method of Structure 6, wherein the organic electronics material comprises an organic electroluminescence material.

(Structure 8) The coating method of Claim 6, wherein the organic electronics material comprises an organic photoelectric conversion element material.

(Structure 9) A coating apparatus coating via the coating method of any one of Structures 1-8.

### EFFECT OF THE INVENTION

Plural coating solutions such as a coating solution formed from an organic EL material and another coating solution formed from an organic photoelectric conversion element material are possible to be coated onto a support in one pass with no mutual mixture of the coating solutions to prepare a multilayer coating film in one pass via the above-described Structures. This can reduce the number of winding up a support on which the coating film is formed, and also achieve improved quality of the coating film surface and improved yield of products.

### BRIEF DESCRIPTION OF THE DRAWINGS

FIG. 1 is a schematic illustration diagram of a coating apparatus by using a coating method of the present invention.

FIG. 2 is an enlarged side view illustration of the coating apparatus shown in FIG. 1.

FIG. 3 is a schematic plan view of showing an example of an installation array of inkjet heads.

FIG. 4 is a configuration cross-sectional view of an atmospheric plasma discharge treatment apparatus.

### EXPLANATION OF NUMERALS

1 Support
2 Backup roll
10, 20, and 30 Coating unit
11 and 12 Coater
12 and 22 Liquid-feeding pump
13, 23, and 33 Coating solution tank
111 and 211 Slit
31 Inkjet
311 Inkjet head
35 Roll rotation electrode
36 Rectangular tube type electrode
40 Electric field application device
50 Gas supply device
60 Electrode temperature adjustment device

### DESCRIPTION OF THE PREFERRED EMBODIMENTS

Next, embodiments of the present invention will be described referring to figures, but the present invention is not limited thereto.

When the present invention is applied to an organic EL element, preferred examples of a layer structure thereof are specifically shown below, but these are not limited to the following embodiments.

### <<Organic EL Element>>

Organic EL elements usable in the present invention are not specifically limited, and The organic EL elements each may be an element possessing an anode, a cathode and at least one organic layer provided between the anode and the cathode, and may be an element to produce luminescence via application of current.

Examples of the emission type include a fluorescence type in which a fluorescence emission compound is employed, a phosphorescence type in which a phosphorescence emission compound is employed, and a combination type in which the fluorescence emission compound and the phosphorescence emission compound are used in combination, but any one of these may be allowed to be used. The phosphorescence type organic EL element is preferable in view of excellent efficiency.

### <<Structure of Organic EL Element>>

An organic EL element to which the present invention is applied is composed of constituent elements such as a support, an electrode, an organic electroluminescence functional solution exhibiting various functions, and so forth. Specific examples of the preferable structure are shown below, but the present invention is not limited thereto.

(i) anode/hole transport layer/electron block layer/emission layer unit/hole block layer/electron transport layer/cathode

(ii) anode/hole transport layer/electron block layer/emission layer unit/hole block layer/electron transport layer/cathode buffer layer/cathode

(iii) anode/anode buffer layer/hole transport layer/electron block layer/emission layer unit/hole block layer/electron transport layer/cathode

(iv) anode/anode buffer layer/hole transport layer/electron block layer/emission layer unit/hole block layer/electron transport layer/cathode buffer layer/cathode

As described above, layers are multilayered to form an organic EL layer.

### <<Support>>

As a support, transparent resin films are utilized.

Examples of resins used for the resin films include polyesters such as polyethylene terephthalate (PET) and polyethylene naphthalene (PEN); polyethylene; polypropylene; cellophane; cellulose esters such as cellulose diacetate, cellulose triacetate, cellulose acetate butyrate, cellulose acetate propionate (CAP), cellulose acetate phthalate (TAC) and cellulose nitrate; or derivatives thereof; polyvinylidene chloride; polyvinyl alcohol; polyethylene vinylalcohol; syndiotactic polystyrene, polycarbonate; a norbornene resin; polymethylpentene; polyether ketone; polyimide; polyether sulfone (PES); polyphenylene sulfide; polysulfones; polyether imide; polyether ketone imide; polyamide; a fluorine resin; polymethyl methacrylate, acryls or polyallylates; and cycloolefin type resins such as ARTON (product name, manufactured by JSR Corp.) and APEL (product name, manufactured by Mitsui Chemicals, Inc.).

It is preferable to appropriately form gas barrier film on the surface of resin film utilized as a support. Gas barrier film includes film of an inorganic substance, an organic substance or hybrid film of the both. As the characteristic of gas barrier film, a water vapor permeability {at 25±0.5° C. and relative humidity of (90±2) % RH}, which is measured based on JIS K 7129-1992, is preferably 0.01 g/(m²·24 h) or less.

Further, a film exhibiting high barrier capability such as an oxygen permeability, which is measured based on JIS K 7126-1987, of 10⁻³ ml/(m²·24 h·MPa) or less and a water vapor permeability {at 25±0.5° C. and relative humidity of (90±2) % RH}, which is measured based on JIS K 7129-1992, of 10⁻⁵ g/(m²·24 h) or less is preferable.

As a material to form a barrier film, preferable is a material provided with a function to restrain invasion of such as moisture and oxygen which may induce deterioration, and such as silicon oxide, silicon dioxide and silicon nitride can be utilized. Further, to overcome brittleness of said film, it is more preferable to provide an accumulation structure comprising an inorganic layer and a layer comprising an organic material. The order of accumulation of an inorganic layer and an organic layer is not specifically limited; however; it is preferable to alternately accumulate the both in plural times. A forming method of barrier film is not specifically limited, and such as a vacuum evaporation method, a sputtering method, a reactive sputtering method, a molecular beam epitaxy method, a cluster ion beam method, an ion plating method, a plasma polymerization method, an atmospheric pressure plasma polymerization method, a plasma CVD method, a laser CVD method, a thermal CVD method and a coating method can be utilized, however, an atmospheric pressure plasma polymerization method such as described in Japanese Patent O.P.I. Publication No. 2004-68143 is specifically preferable.

### <<Anode>>

As an anode (first pixel electrode), those employing a metal, an alloy, a conductive compound and mixtures thereof having a large work function (not less than 4 eV) as an electrode substance are preferably utilized. Specific examples of such an electrode substance include a metal such as Au and a conductive transparent material such as CuI, indium tin oxide (ITO), SnO₂ and ZnO. Further, a material capable of forming amorphous and transparent conductive film such as IMO (In₂O₃.ZnO) may be also utilized. As an anode (first pixel electrode), a pattern of a desired form may be formed by a photolithographic method after forming thin film of an electrode substance by a method such as evaporation or sputtering, or the pattern may be formed through a mask of a desired form at the time of evaporation or sputtering of the above-described electrode substance in the case of patterning precision being not much required (roughly at least 100 μm). Further, in the case of utilizing a substance capable of being coated such as an organic conductive compound, a wet film forming method such as a printing method and a coating method can be also utilized. When emission is taken out from this anode (first pixel electrode), the transmittance is desirably made to be not less than 10%, and a sheet resistance as an anode is preferably a few hundreds Ω/□ or less. Further, a layer thickness depends on a material, but is selected in a range of generally 10-1000 nm and preferably 10-200 nm.

### <<Organic Electroluminescence Functional Solution>>

The organic electroluminescence functional solution employed in the present invention will be described.

As the organic electroluminescence functional solution of the present invention, provided is a solution in which an organic EL material to form a functional layer constituting the after-mentioned organic EL element of the present invention (referred to also as organic EL element functional layer, organic layer, organic compound layer or the like) such as a hole transport layer, an emission layer and an electron transport layer is dissolved in a solvent, or a dispersion in which the foregoing organic EL material is dispersed in a solvent.

Further, the organic EL element material in the organic electroluminescence functional solution preferably has a content of 0.1-10% by weight. The foregoing content range is the solid content when the organic electroluminescence functional solution, but the similar value range is preferable.

### <<Solvent (Medium) Used for Preparation of Organic Electroluminescence Functional Solution>>

The solvent used for preparation of the organic electroluminescence functional solution of the present invention is not specifically limited, and can be appropriately selected, but a solvent having a low boiling point is preferable in view of reduction of time up to completion of drying after coating.

In the present invention, provided is a coating method to form a multilayer coating film layered by coating plural coating solutions onto a long length support, possessing the steps of providing plural coating units each facing a backup roll and sandwiching the support with the backup roll, and coating the plural coating solutions onto the support by the plural coating units to form the multilayer coating film. For this case, at least one solvent among the foregoing plural coating solutions preferably has a boiling point of 120° C. or less. It is more preferable that all of the solvents used in the plural coating solutions each have a boiling point of 120° C. or less, and an organic solvent having a boiling point of 90° C. or less is most preferable. As the solvent, an organic solvent is preferable, and examples thereof include that halogen based solvents such as chloroform, dichloromethane and 1,2-dichloroethane; ketone based solvents such as acetone, methyl ethyl ketone and diethyl ketone; aromatically based solvents such as benzene and so forth; ester based solvents such as ethyl acetate and so forth; ether based solvents such as tetrahydrofuran and dioxane; alcohol based solvents such as methanol, ethanol and 1-butanol; nitrile based solvents such as acetonitrile and so forth; and these mixture solvents.

### <<Anode Buffer Layer>>

An anode buffer layer (hole injection layer) may be provided between an anode and an emission layer or hole transport layer. The hole injection layer is a layer provided between the electrode and an organic layer to improve the driving voltage drop and emission luminance, which is described in detail on pages 123-166, Chapter 2 of Section 2 “Electrode material” of “Yuuki EL Soshi to sono Kogyoka Saizensen (Organic EL element and Forefront of Industrialization of it)” NTS Co., Ltd., (Nov. 30, 1998). The anode buffer (hole injection layer) is described in detail in Japanese Patent O.P.I. Publication Nos. 9-45479, 9-260062 and 8-288069, and a phthalocyanine buffer layer typified by copper phthalocyanine, an oxide buffer layer typified by vanadium oxide, an amorphous carbon buffer layer, and a polymer buffer layer using a conductive polymer such as polyaniline (EMERALDINE) and polythiophene are cited as concrete examples.

### <<Hole Transport Layer>>

A hole transport layer is comprised of a hole transport material having a function to transport holes, and a hole injection layer and an electron block layer are also included in a hole transport layer. A hole transport layer may be provided as a single layer or plural layers. A hole transport material is one exhibiting transport capability of holes, or blocking capability against electrons, and may be either an organic substance or an inorganic substance. For example, listed are triazole derivatives, oxazole derivatives, imidazole derivatives, polyarylalkane derivatives, pyrazoline derivatives and pyrazolone derivatives, phenylenediamine derivatives, arylamine derivatives, amino substituted calcon derivatives, oxazole derivatives, styrylanthrathene derivatives, fluorenone derivatives, hydrazone derivatives, stilbene derivatives, silazane derivatives, aniline type copolymer and conductive polymer oligomer and specifically thiophene oligomer.

As a hole transport material, the above-described ones can be utilized, however; a porphyrin compound, an aromatic tertiary amine compound and a styrylamine compound are preferably utilized and an aromatic tertiary amine compound is specifically preferably utilized. Typical examples of an aromatic tertiary amine compound and a styrylamine compound include N,N,N′,N′-tetraphenyl-4,4′-diaminophenyl; N,N′-diphenyl-N,N′-bis(3-methylphenyl)-[1,1′-biphenyl]-4,4′-diamine (TPD); 2,2-bis(4-di-p-tolylaminophenyl)propane; 1,1-bis(4-di-p-tolylaminophenyl)cyclohexane; N,N,N′,N′-tetra-p-tolyl-4,4′-diaminobiphenyl; 1,1-bis(4-di-p-tolylaminophenyl)-4-phenylcyclohexane; bis(4-dimethylamino-2-methylphenyl)phenylmethane; bis(4-di-p-tolylaminophenyl)phenylmethane; N,N′-diphenyl-N,N′-di(4-methoxyphenyl)-4,4′-diaminobiphenyl; N,N,N′,N′-tetraphenyl-4,4′-diaminodiphenyl ether, 4,4′-bis(diphenylamino)quardoriphenyl; N,N,N-tri(p-tolyl)amine; 4-(di-p-tolylamino)-4′-[4-(di-p-tolylamino)stilyl]stilben; 4-N,N-diphenylamino-(2-diphenylvinyl)benzene; 3-methoxy-4′-N,N-diphenylaminostilben; and N-phenylcarbazole, and further, those having two condensed aromatic rings in a molecule which are described in U.S. Pat. No. 5,061,569 such as 4,4′-bis[N-(1-naphtyl)-N-phenylamino]biphenyl (NPD) and such as 4,4′,4″-tris[N-(3-methylphenyl)-N-phenylamino]triphenylamine (MTDATA), in which three triphenylamine units are connected in a star burst limn, described in Japanese Patent O.P.I. Publication No. 4308688.

Further, a polymer material, in a polymer chain of which these materials have been introduced, or in which these materials are employed as the polymer main chain, can be utilized. Further, an inorganic compound of such as p-type Si and p-type-SiC can be also utilized as a hole injection material or a hole transport material.

Further, a so-called p-type hole transport material such as described in Japanese Patent O.P.I. Publication No. 11-251067 and Applied Physics Letters 80, p. 139 (2002) by J. Huang et al. is usable. In the present invention, these materials are preferably utilized because an emitting element exhibiting higher efficiency can be obtained.

The layer thickness of a hole transport layer is not specifically limited, but is generally about 5 nm-5 μm, and preferably 5-200 nm. This hole transport layer may be provided with one layer structure having one type or not less than two types of the above-described materials. Further, a hole transport layer which is doped with an impurity to have a high p property can also be utilized. The examples include those described in such as Japanese Patent O.P.I. Publication Nos. 4-297076, 2000-196140 and 2001-102175; and J. Appl. Phys., 95, 5773 (2004). It is preferable to utilize such a hole transport layer having a high p property because an organic EL element exhibiting lower power consumption can be prepared.

### <<Emission Layer>>

In the present invention, an emission layer means a blue emission layer, a green emission layer or a red emission layer. The order of accumulation of emission layers in the case of accumulating emission layers is not specifically limited, and further, a non-emission intermediate layer may be provided between each emission layer. In this invention, at least one blue emission layer is preferably arranged at a position nearest to an anode among all emission layers. Further, when not less than four emission layers are arranged, a blue emission layer, a green emission layer and a red emission layer are preferably accumulated in this order from the nearest to an anode, such as a blue emission layer/a green emission layer/a red emission layer/a blue emission layer, a blue emission layer/a green emission layer/a red emission layer/a blue emission layer/a green emission layer, a blue emission layer/a green emission layer/a red emission layer/a blue emission layer/a green emission layer/a red emission layer, in order to enhance luminance stability. It is possible to prepare a white emitting element by using an emission layer composed of plural layers.

The total layer thickness of an emission layer is not specifically limited, however, is selected generally in a range of 2 nm-5 μm and preferably 2-200 nm, in consideration of such as homogeneousness of the film and voltage required for emission. It is furthermore preferably in a range of 10-20 nm. The layer thickness is preferably set to not more than 20 nm because that there is an effect to improve stability of emission color against drive current in addition to voltage aspect. A layer thickness of each emission layer is preferably selected in a range of 2-100 nm and more preferably in a range of 2-20 nm. When an emission layer composed of plural layers are formed, the relationship of layer thickness of each emission layer of blue, green and red is not specifically limited; however, it is preferable that a blue emission layer (as the total when plural layers are present) has the largest layer thickness among three emission layers.

When an emission layer is composed of plural layers, the emission layer preferably possesses at least three layers having different emission spectra, the emission maximum wavelengths of which are in a range of 430-480 nm, 510-550 nm and 600-640 nm, respectively. In the case of 4 layers or more, there may be plural layers having the same emission spectrum. A layer having an emission maximum wavelength of 430-480 nm is referred to as a blue emission layer; a layer having an emission maximum wavelength of 510-550 nm is referred to as a green emission layer, and a layer having an emission maximum wavelength of 600-640 nm is referred to as a red emission layer. Further, in a range of maintaining the aforesaid maximum wavelength, plural number of emission compounds may be mixed in each emission layer. For example, in a blue emission layer, a blue emitting compound having a maximum wavelength of 430-480 nm and a green emitting compound having a maximum wavelength of 510-550 nm may be utilized by being mixed.

Materials utilized in the emission layer are not specifically limited, and includes various types of materials such as described in the new trend of flat panel display; The present situation and the new technical trend of EL display, edited by Toray Research Center Co., Ltd., pp. 228-332.

A process to form a hole transport layer and an emission layer as constituent layers of an organic EL element is preferably conducted under a dew point of not higher than −20° C., a cleanliness degree, which is measured in accordance with JISB 9920, of not higher than class 5, an atmospheric pressure of 10-45° C. except the drying process. In this invention, a cleanliness degree of not higher than 5 indicates class 3-class 5.

### <<Electron Transport Layer>>

An electron transport material (serving also as an electron block material) employed for an electron transport layer adjacent to the emission layer side is provided with a function of transmitting an election injected from an electrode to an emission layer and can be arbitrarily selected from conventionally known compounds, and usable examples thereof include nitro substituted fluorene derivatives, diphenylquinone derivatives, thiopyraneoxide derivatives, carbodiimide, fluorenyliden methane derivatives, anthraquinodimethane and anthrone derivatives, and oxadiazole derivatives. Further, thiadiazole derivatives in which an oxygen atom of an oxadiazole ring is substituted by a sulfur atom in the above-described oxadiazole derivatives, and quinoxaline derivatives having a quinoxaline ring which is known as an electron attracting group can be also utilized as an electron transport material. Further, polymer materials, in which these material is introduced into a polymer chain or these materials are employed as a polymer main chain, can also be utilized.

Further, metal complexes of an 8-quinolinol derivative such as tris(8-quinolinol)aluminum (Alq), tris(5,7-dichloro-8-quinolinol)aluminum, tris(5,7-dibromo-8-quinolinol)aluminum, tris(2-methyl-8-quinolinol)aluminum, tris(5-methyl-8-quinolino)aluminum and bis(8-quinolinol)zinc (Znq), and in addition to these, metal complexes in which the central metal of these metal complexes is replaced by In, Mg, Cu, Ca, Sn, Ga or Pb can also be utilized as an electron transport material. In addition, metal-free or metal phthalocyanine, or those the terminal thereof is substituted by such as an alkyl group or a sulfonic acid group can be also preferably utilized as an electron transport material. Further, a distyrylpyradine derivative can be also utilized as an electron transport material, and similar to the cases of a hole injection layer and a hole transport layer, inorganic semiconductors of such as n-type Si and n-type SiC can be also utilized as an election transport material. The layer thickness of an electron transport layer is not specifically limited; however, is generally approximately 5 nm-5 μm and preferably 5-200 nm. An electron transport layer may have one layer structure having one kind or at least two kinds of the above-described materials.

Further, an electron transport layer which is doped with impurities to provide a high n-property may be also utilized. Such examples includes those described in such as Japanese Patent Publication Nos. 4-297076, 10-270172, 2000-196140 and 2001-102175, and J. Appl. Phys., 95, 5773 (2004). To utilize such an electron transport layer having a high n-property is preferred because an element exhibiting low power consumption can be prepared. An electron transport layer can be also formed by making the above-described electron transport material into a thin film by a method well known in the art such as a wet coating method and a vacuum evaporation method.

### <<Cathode Buffer Layer>>

The cathode buffer layer (electron injection layer) is formed of a material having a function to transport electrons, and is included in a electron transport layer in a broad sense. The hole injection layer is a layer provided between the electrode and an organic layer to improve the driving voltage drop and emission luminance, which is described in detail on pages 123-166, Chapter 2 of Section 2 “Electrode material” of “Yuuki EL Soshi to sono Kogyoka Saizensen (Organic EL element and Forefront of Industrialization of it)” NTS Co., Ltd., (Nov. 30, 1998). A cathode buffer layer (electron injection layer) is also detailed in Japanese Patent Publication Nos. 6-325871, 9-17574 and 10-74586, and specific examples thereof include a metal buffer layer typified by strontium, aluminum and so forth, an alkali metal compound buffer layer typified by lithium fluoride, an alkali earth metal compound buffer layer typified by magnesium fluoride, and an oxide buffer layer typified by aluminum oxide. The above-described buffer layer (injection layer) is preferably a very thin layer, and a layer thickness thereof is preferably in a range of 0.1 nm-5 μm, depending on the material.

### <Cathode>

As a cathode (the second pixel electrode), metal, alloy, a conductive compound or a mixture thereof having a small work function (not more than 4 eV) is utilized as an electrode material. Specific examples of such the electrode material include sodium, sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture and rare earth metal. Of these, in view of an electron injection property and durability against oxidation, a magnesium/silver mixture, a magnesium/aluminum mixture, a magnesium/indium mixture, an aluminum/aluminum oxide (Al₂O₃) mixture and a lithium/aluminum mixture, and aluminum are preferable as a mixture of an electron injecting metal with the second metal which is a stable metal having a large work function. The cathode can be prepared by forming a film a method by which the electrode material is evaporated or sputtered. Further; the sheet resistance of cathode is preferably several 100Ω/□ or less. The film thickness is generally 10 nm-5 μm, and preferably of 50-200 nm. In addition, to transmit emitted light, either the first pixel electrode (anode) of an organic EL element or the second pixel electrode (cathode) of the organic EL element is desired to be transparent or translucent since emission luminance is improved.

Further, after preparing 1-20 nm thick metal described above on a cathode (the second pixel electrode), a transparent or translucent cathode (the second pixel electrode) is possible to be prepared by forming a conductive transparent material described in explanation of the first pixel electrode thereon. An element exhibiting transparency for both an anode (the first pixel electrode) and a cathode (the second pixel electrode) is possible to be prepared via application of the above-described.

Preferable examples of the layer structure in the case of an organic photoelectric conversion element applied for the present invention are described below, but the present invention is not limited to the following embodiment

### <<Organic Photoelectric Conversion Element>>

The organic photoelectric conversion element employed in the present invention is not specifically limited, and may be an element generating current when the element is exposed to light, which possesses an anode, a cathode and at least one layer as an electric power generation layer between the anode and the cathode.

The structure of the electric power generation layer is not specifically limited as long as it is a multilayer structure obtained by layering organic semiconductor, and examples thereof include a heterojunction type structure obtained by layering both a p-type semiconductor material and an n-type semiconductor material to form a multilayer film and a so-called bulk heterojunction type structure obtained by mixing a p-type semiconductor material and an n-type semiconductor material to obtain a micro layer separation structure. A structure having excellent charge separation efficiency is preferable in view of improved internal quantum efficiency, and the bulk heterojunction type structure is more preferable in the case of the present invention.

In cases where an organic photoelectric conversion element of the present invention is used for a solar battery, an organic semiconductor material exhibiting best suited absorption property to solar spectrum is preferably usable, and the organic photoelectric conversion element having black appearance is preferable in view of efficiency and designing.

### <<Structure of Organic Photoelectric Conversion Element>>

An organic photoelectric conversion element of the present invention possesses a transparent electrode, an electric power generation layer, and a pair of electrodes sequentially layered on one surface of a support.

Aside from this, other layers such as a hole transport layer, an electron transport layer, a hole block layer, an electron block layer, an electrode buffer layer and a smoothing layer may be provided between the electric power generation layer and the transparent electrode, or the electric power generation layer and a pair of the electrodes to constitute the organic photoelectric conversion element. Further, it may be a hole transport layer exhibiting hole blocking ability or electron blocking ability. Charge generated in a bulk heterojunction type electric power generation layer is possible to be effectively taken out by forming at least one of a hole transport layer and an electron block layer between an electric power generation layer and an anode (generally on the side of a transparent electrode), and at least one of an electron transport layer and a hole block layer between an electric power generation layer and a cathode (generally on a pair of the electrodes), whereby among these, an organic photoelectric conversion element having the bulk heterojunction type electric power generation layer preferably has the foregoing layers.

(i) anode/hole transport layer/electron block layer/electric power generation layer/hole block layer/electron transport layer/cathode

(ii) anode/hole transport layer exhibiting electron blocking ability/electric power generation layer/electron transport layer exhibiting hole blocking ability/cathode buffer layer/cathode

(iii) anode/anode buffer layer/hole transport layer/electron block layer/electric power generation layer/hole block layer/electron transport layer/cathode

(iv) anode/anode buffer layer/hole transport layer/electron block layer/electric power generation layer/hole block layer/electron transport layer/cathode buffer layer/cathode

As described above, an organic photoelectric conversion element is obtained by layering each layer to prepare a multilayer. In addition, the thin film forming method of the present invention can be applied to form each structure described above, but specifically applied preferably to form each layer other than the anode and the cathode.

### <<Coating>>

As a method of coating a functional solution used for organic electroluminescence and an organic photoelectric conversion element, various methods have been commonly known so far.

In the present invention, a slot type coater coating system or an inkjet coating system is preferable in order to form a very thin single layer as a coating film.

When using a slot type coater, a reduced pressure chamber is provided upstream of the coater, and a bead section is supported in a state of reduced pressure to further improve coating evenness. The reason is that the wetted location of the coating solution remains almost unmoved even though surface nature and wettability of a support are varied by depressurizing the lower portion of a bead, whereby a coating film having a uniform thickness can be obtained.

The slot type coater coating system is a system by which at least two coater dies are provided in combination, a coating solution supplied flow a coating solution supply device expands in the width direction at a pocket portion of the coater die and flows at an even flow rate in the width direction from the slit section to directly coat the coating solution expanding in the width direction on the support in even coating film thickness. As previously described, it is of a further preferred embodiment that the reduced pressure chamber is placed upstream of the coater die.

Inkjet heads are not specifically limited. For example, it may be a thermal type head fitted with a heater element, by which a coating solution is ejected from a nozzle via rapid volume change generated by film boiling of the coating solution caused by thermal energy from this heater element, and may be a shear mode type (piezo type) head equipped with a vibration plate, by which a coating solution is ejected via pressure change of an ink pressure chamber generated by this vibration plate, but the shear mode type (piezo type) head is preferable in view of stability of the coating solution.

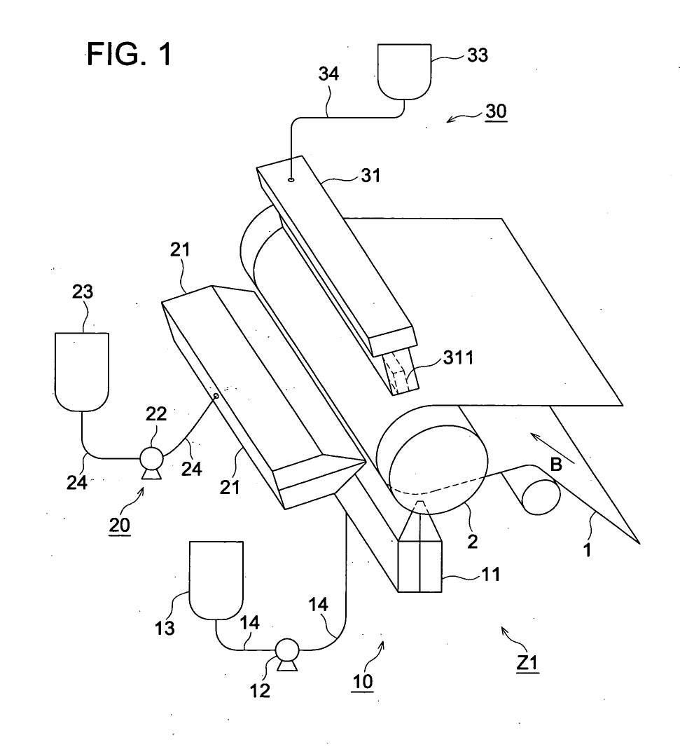

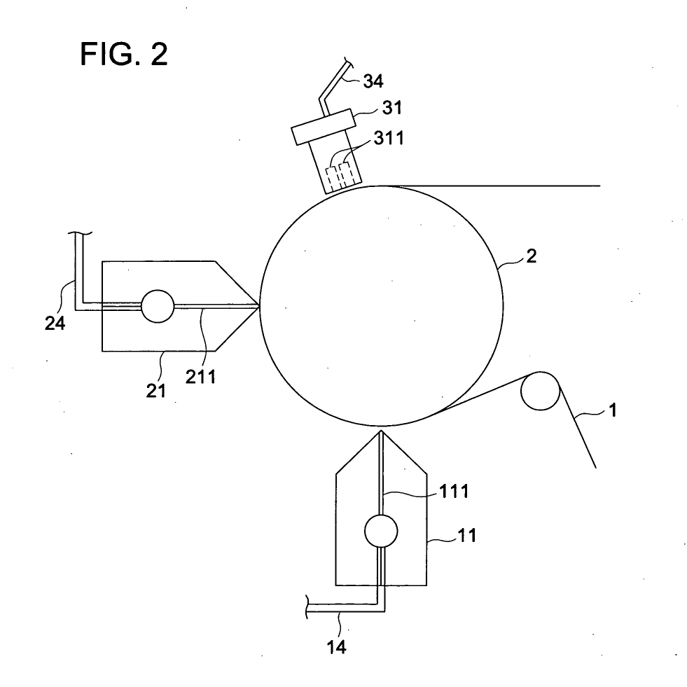

FIG. 1 is a schematic illustration diagram of a coating apparatus by using a coating method of the present invention. FIG. 1 shows an example in which three kinds of coating solutions are coated via layering to form a coating film composed of three layers, where two layers are coated with a slot type coater (hereinafter, referred to also as a coater), and one layer is coated via inkjet. FIG. 2 is an enlarged side view illustration obtained by viewing the coating apparatus shown in FIG. 1 from the arrow Z1 direction. Coaters 11 and 21 each show a cross-sectional view.

Long length support 1 wound in the form of a roll is conveyed by forwarding the support in the arrow B direction from a wind-off roll (not shown in the figure) with a drive unit (not shown in the figure).

Long length support 1 is conveyed so as to be supported by backup roll 2, and coating solutions are sequentially coated layer by layer employing coater 11 in coating unit 10 as a coating device, coater 21 in coating unit 20, and inkjet head 311 provided in inkjet unit 31 in mating unit 30 to form a multilayer coating film composed of three layers. The resulting multilayer coating film is rolled by a wind-up roll (not shown in the figure) after drying the multilayer coating film in the drying section (not shown in the figure).

Coating unit 10 is equipped with coater 11, liquid-feeding pump 12, coating solution tank 13, and coating solution supply tube 14. Liquid-feeding pump 12 supplies a coating solution stored in coating solution tank 13 into coater 11 via coating solution supply tube 14. Coater 11 equipped with slit 111 suited for the coating width in the support width direction, facing backup roll 2, and sandwiching support 1 with the backup roll is provided. Coater 11 conducts coating by ejecting a coating solution onto support 1 from slit 111. Coating unit 10 also has a function to evenly eject a coating solution in the width direction of support 1 from slit 111.

Coating unit 20 is equipped with coater 21, liquid-feeding pump 22, coating solution tank 23, and coating solution supply tube 24. Coating unit 20 has the same function as described in coating unit 10.

Coating unit 30 is equipped with inkjet unit 31, inkjet head 311 provided in inkjet unit 31, coating solution tank 33, and coating solution supply tube 34. Inkjet head 311 facing backup roll 2, and sandwiching support 1 with the backup roll is provided. A coating solution stored in coating solution tank 33 is supplied into inkjet head 311 via coating solution supply tube 34, and is ejected to support 1 from a nozzle of inkjet head 311. Through this, the coating solution is coated on support 1. The coating solution is ejected nearly in the direction of rotation center of backup roll 2 from a nozzle of inkjet head 311.

The number of inkjet heads 311 and the array of inkjet heads 311 are arbitrarily arranged to be placed in inkjet unit 31. The number and array are appropriately selected depending on the utilized coating solution, the coating condition, the ejection width of inkjet head 311, the coating width of support 1, and so forth.

Coating unit 30 supplies a coating solution into inkjet head 311, and also has a function to keep coating solution pressure inside inkjet head 311 constant.

Inkjet heads 311 are not specifically limited. For example, it may be a thermal type head fitted with a heater element, by which a coating solution is ejected from a nozzle via rapid volume change generated by film boiling of the coating solution caused by thermal energy from this heater element, and may be a shear mode type (piezo type) head equipped with a vibration plate, by which a coating solution is ejected via pressure change of an ink pressure chamber generated by this vibration plate.

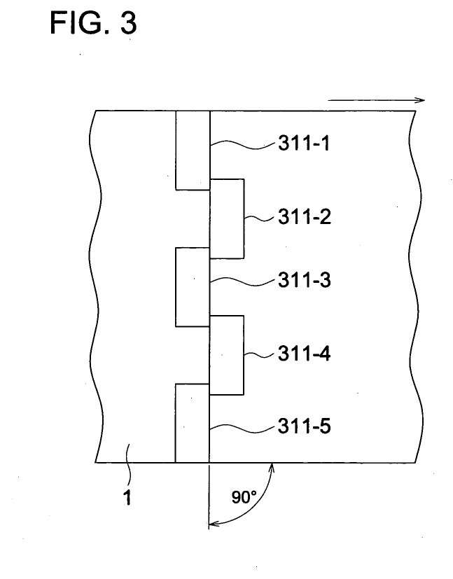

FIG. 3 is a schematic plan view of showing an example of an installation array of inkjet heads 311.

Inkjet heads 311-1 to 311-5 are placed as shown in FIG. 3. The surface possessing a nozzle ejection-opening of each of inkjet heads 311-1 to 311-5 placed at regular intervals is parallel to the coating film surface of support 1, and the inkjet heads are placed in such a way that 90° is an angle between the moving direction of support 1 and a line connecting central points of the nozzle ejection-openings place in the width direction perpendicular to the moving direction of support 1. They are also placed in staggered arrangement in such a way that ends of each of inkjet heads 311-1 to 311-5 are piled on each other to eliminate an uncoated portion between adjacent inkjet heads. A response to the width of support 1 becomes easier by employing plural inkjet heads in such the way and placing the inkjet heads as shown in FIG. 3, and the uncoated portion between the inkjet heads is eliminated, whereby a stable coating film can be prepared.

Coater 11, coater 21 and inkjet head 311 are placed at predetermined intervals along the circumference of backup roll 2.

As previously described, a coating solution as an organic EL material used for an organic EL layer, and a coating solution as an organic photoelectric conversion element material used for an organic photoelectric conversion element layer are easy to be mutually mixed, and are also easy to be dried since they are very thin coating films. They are not mixed because of the drying progress of the first coating solution coated with coater 11 even though the second coating solution is coated with coater 21. Accordingly, when coating is conducted at predetermined intervals, coating layers are laminated with no mixture of the coating solutions. A duration where the coating solutions are not mutually mixed can be set via measurement in experiments in advance with respect to each coating solution. The foregoing predetermined intervals can be set by the duration obtained via the measurement where the coating solutions are not mutually mixed, and the moving speed of support 1. Further, the diameter of backup roll 2 can be set by the foregoing predetermined intervals and the number of coating units provided herein.

In this case, the backup roll preferably has a diameter of 0.5-5 m. In the case of a diameter of less than 0.5 m, the number of the coating units is reduced, and the number of layers coatable in one pass becomes small, whereby manufacturing efficiency drops. Further, when the number of layers coatable in one pass is reduced, the number of times of wind-up is increased, whereby the coating film surface is easily damaged during the foregoing wind-up. In the case of a diameter exceeding 5 m, backup roll 2 is difficult to be prepared, whereby a maintenance property is degraded.

Further, a single layer as a coating layer preferably has a wet coating layer thickness (coating layer thickness of a single layer before drying) of 0.5-10 μm. In the case of a wet coating layer thickness of less than 0.5 μm, it is difficult to conduct coating, the coating layer thickness tends to be fluctuated. In the case of a wet coating layer thickness exceeding 10 μm, it takes a long time for drying, and it is difficult to avoid mutual mixture of coating solutions unless the foregoing predetermined intervals are expanded, resulting in factors of an apparatus in unfavorable large size, and increased cost.

This system preferably has a coating speed of 1-10 m/min, and more preferably has a coating speed of 1-5 m/min. Since the wet coating film thickness is thin, coating can not be stably conducted at high coating speed, resulting in generation of quality defects. Further, the upper layer is coated in the situation where no drying is forwarded when at high coating speed, and interlayer mixture is generated, resulting also in quality defects.

In the embodiment of the present invention, coaters and an inkjet such as two coaters and one inkjet are used in combination, but only coaters or only inkjets may be alternatively allowed to be used. Further, only coaters may be preferably used in order to avoid coating unevenness such as coating streak and so forth.

As described above, plural coating units are provided at predetermined intervals along a support continuously moving via winding of a backup roll, and plural coating solutions as an organic EL material and organic photoelectric conversion element material can be coated in one pass with no mutual mixture of coating solutions by coating to laminate layer by layer on the foregoing support to form a multilayer film. In other words, the multilayer film can be formed on a support in one pass, and the number of times of winding a support on which a coating film is formed can be reduced. By doing this not only quality of the coating layer surface but also product productivity can be improved.

### Example

Next, the present invention is described in detail referring to examples in the case of application to an organic EL element, but the present invention is not limited thereto, and this can be also applied to an organic electronics element such as an organic photoelectric conversion element and so forth.

As an example of a method of preparing an organic EL element of the present invention, described is an organic EL composed of anode/hole transport layer/emission layer/electron transport layer/cathode, but in regard to technique in the scope of claims, those applied only to hole transport layer/emission layer are shown. However, the present invention is not limited to this scope, and various functional layers are allowed to be used.

### Example 1

### Support

A transparent gas barrier film obtained by laminating three layers of a unit possessing a low density layer, a medium density layer, a high density layer and a medium density layer was prepared on a substrate of polyether sulfon (film manufactured by Sumitomo Bakelite Co., Ltd., hereinafter, abbreviated as PES) having a thickness of 200 μm under, employing the following atmospheric plasma discharge treatment apparatus and discharge conditions.

### (Atmospheric Plasma Discharge Treatment Apparatus)

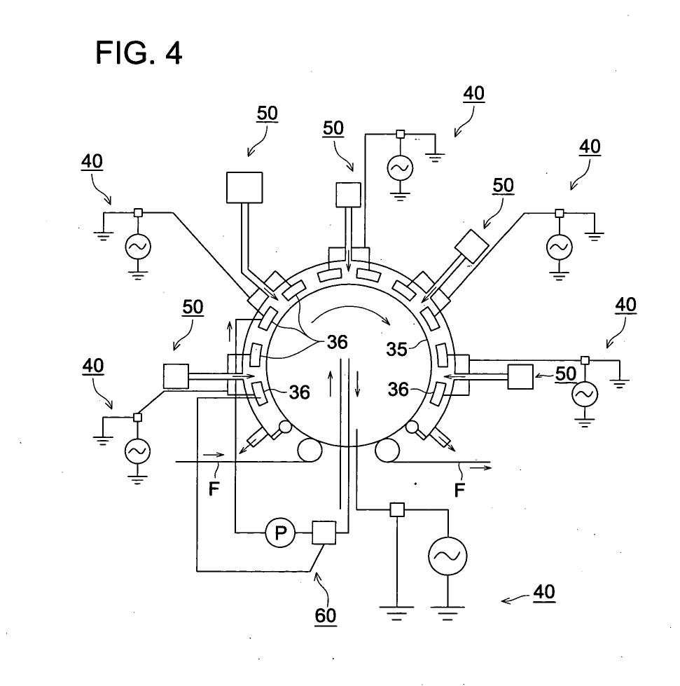

FIG. 4 is a configuration cross-sectional view of an atmospheric plasma discharge treatment apparatus. The atmospheric plasma discharge treatment apparatus is equipped with roll rotation electrode 35 and plural rectangular tube electrode 36 as facing electrodes, electric field application device 40, gas supply device 50 and electrode temperature adjustment device 60.

A set of roll rotation electrode 35 covered with a dielectric and plural rectangular tube type electrode 36 was prepared as described below.

Roll rotation electrode 35 as the first electrode was prepared in such a way that an alumina sprayed film exhibiting high density and high adhesion was coated onto a metal mother material of a titanium alloy T64 metal jacket roll equipped with a cooling device with cooling water by an atmospheric plasma method to have a roll diameter of 1000 mm. On the other hand, rectangular tube type electrode 36 as the second electrode was set to the facing rectangular tube type fixed electrode group by coating 1 mm thick dielectric similar to the above-described on to a hollow rectangular tube type titanium alloy T64 under the same condition.

Twenty rectangular tube type electrodes were placed around roll rotation electrode 35 at a facing electrode gap of 1 mm. The total discharge area of the rectangular tube type electrode group was 150 can (length in the width direction)×4 cm (length in the conveying direction)×24 (the number of electrodes)=14,400 cm².

During plasma discharge, the first electrode (roll rotation electrode 35) and the second electrode (rectangular tube type fixed electrode 36) were subjected to temperature control at 80° C. and roll rotation electrode 35 was driven for rotation, whereby a thin film was formed. Of the above-described 24 rectangular tube type fixed electrodes 36, 4 electrodes from the upstream side were employed to form the first layer (low density layer 1) described below, the subsequent 6 electrodes were employed to form the 2nd layer (medium density layer 1) described below, the following 8 electrodes were employed to form the 3rd layer (high density layer 1), and the remaining 6 electrodes were employed to form the 4th layer (medium density layer 2). Four layers were laminated in one pass, while setting each respective condition. Subsequently, the above conditions were repeated twice, whereby a transparent gas barrier film was prepared.

### (First Layer: Low Density Layer 1)

Plasma discharge was carried out under the following conditions to form about 90 nm thick low density layer 1.

### <Gas Condition>

| | |
|---|---|
| Discharge gas: Nitrogen gas | 94.8% by volume |
| Thin layer forming gas: Hexamethyldisiloxane | 0.2% by volume |
| (hereinafter, abbreviated as HMDSO) | |
| (vaporized via a vaporizer manufactured | |
| by Lintec Co., while blended with nitrogen gas) | |
| Additive gas: Oxygen gas | 5.0% by volume |

### <Power Supply Condition: Only a Power Supply on the First Electrode Side to be Employed>

First electrode side: power supply type, high frequency power
supply manufactured by Oyo Electric Co., Ltd.

| | |
|---|---|
| Frequency | 80 kHz |
| Output density | 10 W/cm² |

Density of the first layer (low density layer) prepared as described above was determined via measurement by an X-ray reflectance method employing MXP21 manufactured by MAC Science Co., Ltd., resulting in a density of 1.90.

### (Second Layer: Medium Density Layer 1)

Plasma discharge was carried out under the following conditions to form about 90 nm thick medium density layer 1.

### <Gas Condition>

| | |
|---|---|
| Discharge gas: Nitrogen gas | 94.9% by volume |
| Thin layer forming gas: Hexamethyldisiloxane | 0.1% by volume |
| (hereinafter, abbreviated as HMDSO) (vaporized | |
| via a vaporizer manufactured by Lintec Co., | |
| while blended with nitrogen gas) | |
| Additive gas: Oxygen gas | 5.0% by volume |

### <Power Supply Condition: Only a Power Supply on the First Electrode Side to be Employed>

First electrode side, power supply type, high frequency power
supply manufactured by Oyo Electric Co., Ltd.

| | |
|---|---|
| Frequency | 80 kHz |
| Output density | 10 W/cm² |

Density of the second layer (medium density layer) prepared as described above was determined via measurement by an X-ray reflectance method employing MXP21 manufactured by MAC Science Co., Ltd., resulting in a density of 2.05.

### (Third Layer: High Density Layer 1)

Plasma discharge was carried out under the following conditions to form about 90 nm thick high density layer 1.

### <Gas Condition>

| | |
|---|---|
| Discharge gas: Nitrogen gas | 94.9% by volume |
| Thin layer forming gas: Hexamethyldisiloxane | 0.1% by volume |
| (hereinafter, abbreviated as HMDSO) (vaporized | |
| via a vaporizer manufactured by Lintec Co., | |
| while blended with nitrogen gas) | |
| Additive gas: oxygen gas | 5.0% by volume |

### <Power Supply Condition>

First electrode side, power supply type, high frequency power
supply manufactured by Oyo Electric Co., Ltd.

| | | |
|---|---|---|
| Frequency | 80 | kHz |
| Output density | 10 | W/cm² |

Second electrode side, power supply type: high frequency power
supply manufactured by Pearl Kogyo Co., Ltd.

| | | |
|---|---|---|
| Frequency | 13.56 | kHz |
| Output density | 10 | W/cm² |

Density of the third layer (high density layer) prepared as described above was determined via measurement by an X-ray reflectance method employing MXP21 manufactured by MAC Science Co., Ltd., resulting in a density of 2.20.

### (Fourth Layer: Medium Density Layer 2)

Medium density Layer 2 was formed under the same conditions as in the above-described 2nd layer (medium density layer 1).

### (5th Layer-12th Layer)

In the same condition as in the formation of the above-described first layer-fourth layer (1 unit), this is repeated to prepare a transparent gas barrier film.

A water vapor permeability of 10⁻³ g/(m²·24 h) or less was obtained via measurement of the water vapor permeability in accordance with JIS K 7129-1992.

An oxygen permeability of 10⁻³ ml/(m²·24 h·MPa) or less was obtained measurement of the oxygen permeability in accordance with JIS K 7126-1987.

### <<Preparation of Anode>>

Next, a 120 nm thick ITO (indium tin oxide) film was formed on the gas bather film substrate by a sputtering method, an evaporation method, an ion plating method or the like to prepare an anode.

A belt-hie flexible sheet in the form of a roll provided with an anode was forwarded, and was subjected to a washing surface modification treatment and an electrification removal treatment, and was subsequently wound up in the form of a roll.

A low pressure mercury lamp, an excimer lamp, a plasma washing apparatus and so forth are usable for the washing surface modification treatment.

In the present Example, a dry washing surface modification treatment apparatus was operated at a low pressure mercury lamp wavelength of 184.9 nm, at an exposure intensity of 15 mW/cm², and at an exposure distance of 10 mm. The surface is modified by this treatment, resulting in removal of organic contaminants and improved wettability.

There are roughly a light exposure system and a corona discharge system as an electrification removal treatment Air ions are produced by very weak X-rays in the case of the light exposure system, but produced by corona discharge in the case of the corona discharge system. These air ions are pulled to a charged substance to make up for opposite polar charge for neutralization of static electricity. Neutralization apparatuses taking advantage of corona discharge and soft X-rays are to be usable.

In the present Example, a neutralization apparatus taking advantage of very weak X-rays was employed. Since charge is removed from a substance, dust adhesion and insulation breakdown are inhibited, resulting in an improved yield ratio of the elements.

### <<Preparation of Hole Transport Layer Coating Solution>>

Polyethylenedioxythiphene-polystyrene sulfonate (PEDOT/PSS, Baytron P Al 4083 produced by Bayer AG.) was diluted by 70% with methanol to prepare a hole transport layer coating solution.

### <<Preparation of Emission Layer Coating Solution>>

Five % by weight of Ir(ppy)₃ as a green dopant material was mixed with polyvinyl carbazole (PVK) as a host material and was dissolved in 1,2-dichloroethane, and a solution having a solid content of 1% by weight was made.

### <<Coating of Hole Transport Layer/Emission Layer>>

Employing a backup roll (hereinafter, abbreviated as BR) having a diameter of 3 m, and a slot type coater, both solutions for a hole transport layer and an emission layer were coated at a coating speed of 4 m/min so as to give a wet coating layer thickness of the lower layer of 2.5 μm, and a wet coating layer thickness of the upper layer of 5 μm. One coater was placed 5 m away from another coater.

### <<Hole Transport Layer/Drying of Emission Layer/Aftertreatment>>

As to a solvent removal treatment in the present Example, the solvent was removed in a dry treatment process with heated air current after coating. This was conducted at a height of 10 mm toward the film-forming surface from an ejection opening in the slit nozzle form, at an ejecting wind speed of 1 m/s, at a width distribution of 5 m, and at a drying temperature of 100° C. As for a drying furnace, the conditions of temperature and wind speed are possible to be changed by appropriately setting a few zones, depending on the material constituting an organic compound layer.

In a heat treatment process of the present Example, after removing the solvent, a substrate is conveyed while adsorbing it via suction from a spacing between rolls heated to 150° C. to conduct a heat treatment of heating via back surface heat transfer. The present example is an example, and the present invention is not limited to this example and does not persist in the form, as long as heat is transferred from the back surface. The heat treatment is preferably conducted at a glass transition temperature±50° C. and at a temperature not exceeding a decomposition temperature, together with back surface heat transfer. Smoothness of the film and removal of the remaining solvent are achieved by conducting a heat treatment, and element characteristics obtained during lamination are improved by curing the coating film.

A roll having been wound up is stored at a reduced pressure of 10⁻⁶-10⁻² Pa, and temperature may be appropriately applied. A storing duration of 1-200 hours is preferable, and a longer duration is more preferable. By doing this, oxygen and a very small amount of water content originated by element degradation are removed.

### <<Electron Transport Layer and Cathode>>

As an example of a post process after forming the foregoing emission layer, as for the above-described resulting film in the form of a roll, compound (2) as an electron transport material was evaporated onto the entire surface of an anode at a vacuum degree of 5×10⁻⁴ Pa employing an evaporation head provided above the emission layer to form an electron transport layer having a thickness of 20 nm. Next, a LiF layer having a thickness of 0.5 nm was evaporated onto the electron transport layer.

Subsequently, 100 nm thick aluminum layers were similarly evaporated onto the region of an organic EL layer, and onto the region including a region where an electrode was exposed in this order. After this, a 300 nm thick inorganic film made of SiOx, SiNx or a composite material was formed on the non-electrode region as a sealing film by a sputtering method, a plasma CVD method, or an ion plating method, and the resulting was wound up to obtain an organic EL element of Example 1 (the present invention).

### Example 2

### Support

The same film as in Example 1 was employed to prepare a transparent gas barrier film by the same method.

### <<Preparation of Anode>>

After an anode was prepared by the same method as in Example 1, the same surface treatment was carried out

### <<Preparation of Hole Transport Layer Coating Solution>>

Polyethylenedioxythiphenepolystyrene sulfonate (PEDOT/PSS, Baytron P Al 4083 produced by Bayer AG.) was diluted by 70% with methanol to prepare a hole transport layer coating solution.

### <<Preparation of Emission Layer Coating Solution>>

Five % by weight of Ir(ppy)₃ as a green dopant material was mixed with polyvinyl carbazole (PVK) as a host material, and dissolved in 1,2-dichloroethane. Only the amount of solvent was changed, and a solution having a solid content of 2% by weight was made.

### <<Coating of Hole Transport Layer/Emission Layer>>

Employing a backup roll having a diameter of 4.5 m, a slot type coater for a hole transport layer, and an inkjet coating apparatus for an emission layer, both solutions for the hole transport layer and the emission layer were coated at a coating speed of 4 m/min so as to give a wet coating layer thickness of the lower layer of 2.5 μm, and a wet coating layer thickness of the upper layer of 2.5 μm. The slot type coater was placed 7 m away from the inkjet coating apparatus.

### <<Hole Transport Layer/Drying of Emission Layer/Aftertreatment>>

Drying and aftertreatment were conducted by the same method as in Example 1.

### <<Electron Transport Layer and Cathode>>

An electron transport layer and a cathode were prepared by the same method as in Example 1, and then a sealing film was provided to obtain an organic EL element of Example 2 (the present invention).

### Example 3

### Support

The same film as in Example 1 was employed to prepare a transparent gas barrier film by the same method.

### <<Preparation of Anode>>

After an anode was prepared by the same method as in Example 1, the same surface treatment was carried out

### <<Preparation of Hole Transport Layer Coating Solution>>

Polyethylenedioxythiphenepolystyrene sulfonate (PEDOT/PSS, Baytron P Al 4083 produced by Bayer AG.) was diluted by 70% with methanol to prepare a hole transport layer coating solution.

### <<Preparation of Emission Layer Coating Solution>>

Five % by weight of Ir(ppy)₃ as a green dopant material was mixed with polyvinyl carbazole (PVK) as a host material, and dissolved in 1,2-dichloroethane. The amount of solvent was changed, and a solution having a solid content of 3% by weight was made.

### <<Coating of Hole Transport Layer/Emission Layer>>

Employing a backup roll having a diameter of 1 m, and an inkjet coating apparatus, both solutions for a hole transport layer and an emission layer were coated at a coating speed of 2 m/min so as to give a wet coating layer thickness of the lower layer of 2 μm, and a wet coating layer thickness of the upper layer of 1.7 μm. One inkjet coating apparatus was placed 2 m away from another inkjet coating apparatus.

### <<Hole Transport Layer/Drying of Emission Layer/Aftertreatment>>

Drying and aftertreatment were conducted by the same method as in Example 1.

### <<Electron Transport Layer and Cathode>>

An electron transport layer and a cathode were prepared by the same method as in Example 1, and then a sealing film was provided to obtain an organic EL element of Example 3 (the present invention).

### Comparative Example 1

### Support

The same film as in Example 1 was employed to prepare a transparent gas barrier film by the same method.

### <<Preparation of Anode>>

After an anode was prepared by the same method as in Example 1, the same surface treatment was carried out

### <<Preparation of Hole Transport Layer Coating Solution>>

The same solution as in Example 1 was prepared.

### <<Preparation of Emission Layer Coating Solution>>

The same solution as in Example 1 was prepared.

### <<Coating of Hole Transport Layer/Emission Layer>>

Employing a backup roll having a diameter of 0.3 m, after a hole transport layer was coated with a slot type coater at a coating speed of 4 m/min so as to give a wet coating layer thickness of 2.5 μm, followed by drying, the resulting was wound up, and again employing the same coating line as before, an emission layer was coated with an inkjet coating apparatus at a coating speed of 4 m/min so as to give a wet coating layer thickness of 5 μm, and dried.

### <<Aftertreatment>>

The aftertreatment was conducted by the same method as in Example 1.

### <<Electron Transport Layer and Cathode>>

An electron transport layer and a cathode were prepared by the same method as in Example 1, and then a sealing film was provided to obtain an organic EL element of Comparative example 1.

### Comparative Example 2

### Support

The same film as in Example 1 was employed to prepare a transparent gas barrier film by the same method.

### <<Preparation of Anode>>

After an anode was prepared by the same method as in Example 1, the same surface treatment was carried out.

### <<Preparation of Hole Transport Layer Coating Solution>>

The same solution as in Example 1 was prepared.

### <<Preparation of Emission Layer Coating Solution>>

The same solution as in Example 1 was prepared.

### <<Coating of Hole Transport Layer/Emission Layer>>

Employing a backup roll having a diameter of 0.3 m, after a hole transport layer was coated with a slot type coater at a coating speed of 4 m/min so as to give a wet coating layer thickness of 2.5 μm, followed by drying, the resulting was wound up, and again employing the same coating line as before, an emission layer was coated also with a slot type coater at a coating speed of 4 m/min so as to give a wet coating layer thickness of 5 μm, and dried.

### <<Aftertreatment>>

The aftertreatment was conducted by the same method as in Example 1.

### <<Electron Transport Layer and Cathode>>

An electron transport layer and a cathode were prepared by the same method as in Example 1, and then a sealing film was provided to obtain an organic EL element of Comparative example 2.

Evaluation

### <<Evaluation of Organic EL Element>>

As to each element of the resulting organic EL element examples 1-3 (the present invention) and comparative examples 1-2, a voltage of 10 V was applied to each of the elements to visually observe the light emission situation in the light emitting portion, and ranking evaluation of the emission characteristics was made based on the following criterion.

### <<Criterion of Ranking Evaluation>>

A: Excellent light emission is produced on the entire surface of the emission portion.

B: Light emission is produced on the entire surface, but luminance unevenness at a level of no practical problem is observed.

C: No light emission is locally observed, but there is no practical problem.

D: A large region of no light emission is observed in the emission portion.

TABLE 1

| | | | | First | | | Second | |
|---|---|---|---|---|---|---|---|---|
| | | | | layer wet | | | Layer wet | |
| | | 1 pass | First | coating | 2 passes | Second | coating | |
| | BR | coating | layer | layer | coating | layer | layer | |
| | diameter | speed | coating | thickness | speed | coating | thickness | Evaluation |
| | (m) | (m/min) | system | (μm) | (m/min) | system | (μm) | result |
| Ex. 1 | 3.0 | 4 | Slot | 2.5 | — | Slot | 5.0 | A |
| Ex. 2 | 4.5 | 4 | Slot | 2.5 | — | Inkjet | 2.5 | B |
| Ex. 3 | 1.0 | 2 | Inkjet | 2.0 | — | Inkjet | 1.7 | C |
| Comp. 1 | 0.3 | 4 | Slot | 2.5 | 4 | Inkjet | 5.0 | D |
| Comp. 2 | 0.3 | 4 | Slot | 2.5 | 4 | Slot | 5.0 | D |

Ex.: Example,
Comp.: Comparative example

The effect produced by the present invention was confirmed as shown above.

1. A coating method to form a multilayer coating film layered by coating plural coating solutions onto a long length support, comprising the steps of:
providing plural coating units each facing a backup roll and sandwiching the support with the backup roll, and
coating the plural coating solutions onto the support by the plural coating units to form the multilayer coating film.

2. The coating method of claim 1,
wherein at least one solvent in the foregoing plural coating solutions has a boiling point of 120° C. or less.

3. The coating method of claim 1,
wherein each single layer of the multilayer coating film has a wet coating layer thickness of 0.5-10 mm.

4. The coating method of claim 1,
wherein each of the plural coating units coats a single coating solution.

5. The coating method of claim 1,
wherein the plural coating units comprise at least one of an inkjet coating system and a slot type coater coating system having a slit to eject the coating solution in a width direction of the support.

6. The coating method of claim 1,
wherein the coating solution comprises an organic electronics material.

7. The coating method of claim 6,
wherein the organic electronics material comprises an organic electroluminescence material.

8. The coating method of claim 6,
wherein the organic electronics material comprises an organic photoelectric conversion element material.

9. A coating apparatus coating via the coating method of claim 1.

10. The coating method of claim 2,
wherein each single layer of the multilayer coating film has a wet coating layer thickness of 0.5-10 mm.

11. The coating method of claim 2,
wherein each of the plural coating units coats a single coating solution.

12. The coating method of claim 3,
wherein each of the plural coating units coats a single coating solution.

13. The coating method of claim 10,
wherein each of the plural coating units coats a single coating solution.

14. The coating method of claim 2,
wherein the coating solution comprises an organic electroluminescence material.

15. The coating method of claim 3,
wherein the coating solution comprises an organic electroluminescence material.

16. The coating method of claim 4,
wherein the coating solution comprises an organic electroluminescence material.

17. The coating method of claim 10,
wherein the coating solution comprises an organic electroluminescence material.

18. The coating method of claim 2,
wherein the coating solution comprises an organic photoelectric conversion element material.

19. The coating method of claim 3,
wherein the coating solution comprises an organic photoelectric conversion element material.

20. The coating method of claim 4,
wherein the coating solution comprises an organic photoelectric conversion element material.

21. The coating method of claim 10,
wherein the coating solution comprises an organic photoelectric conversion element material.
